(19) United States
(12) Patent Application Publication
(10) Pub. No.: US 2007/0279169 A1
(43) Pub. Date: Dec. 6, 2007

(54) Shim tray

(75) Inventors: Richard Gowland, Bicester (GB); Edgar Charles Malcolm Rayner, North Moreton (GB)

Correspondence Address: CROWELL & MORING LLP;INTELLECTUAL PROPERTY GROUP, P.O. BOX 14300, WASHINGTON, DC, 20044-4300, US

(73) Assignee: Siemens Magnet Technology Ltd., Witney (GB)

(21) Appl. No.: 11/802,406

(22) Filed: May 22, 2007

(30) Foreign Application Priority Data
May 22, 2006 (GB) 0610024.2

(51) Int. Cl. G01R 33/38

(52) U.S. Cl. 335/301; 324/320

(57) ABSTRACT

A container is described that is particularly suitable for use as a shim tray. An integral hinged lid and resilient member minimises the number of components that need to be handled during shimming of a superconducting electromagnet. The resilient member dispenses with the need for a selection of packers in order to retain the shims within the container. A slot allows shims to be inserted and retained by the member without removing the lid.

The invention concerns a container adapted to retain contents without freedom of movement and has particular utility in the field of superconducting magnet manufacture.

Existing designs of shim tray include a separate lid and require packers to retain the shims without movement within the container. Hence, each time a tray is filled or has some of the contents removed, a packer must be selected before the lid is replaced.

The present invention offers an improvement to this design such that, in the most preferred embodiment, neither a lid nor packer needs to be selected. A retaining means that is integral with the lid is dispenses with the need to select any components. Thus, the number of components needed during a magnet shimming operation is reduced and the process is made easier.

According to the invention, a packaging container comprises the features set out in claim 1 attached hereto.

Preferrably the resilient element comprises a spring tongue, integral with the lid of the container. The lid of the container may be integral with the container and more preferrably, the container, lid and tongue may be integrated in a single article which conveniently lends itself to manufacture by injection moulding techniques.

A further preferred embodiment includes an opening in the container, being arranged to facilitate insertion of a shim or other article into the container, for retention by the tongue, without removal of the lid.

The invention will now be described by non-limiting example, with reference to the following figures in which

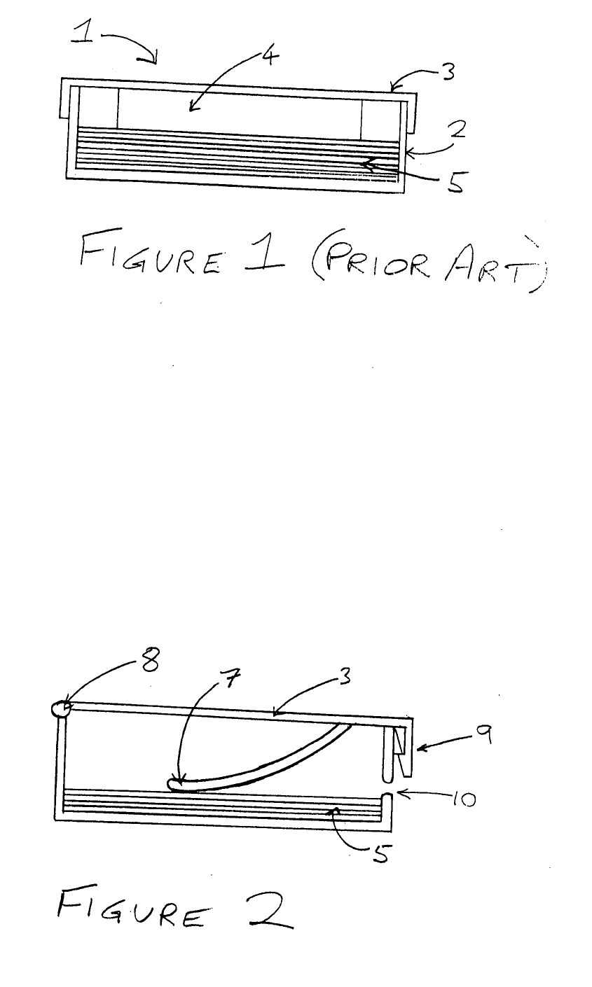

FIG. 1 shows a shim tray according to the prior art and

FIG. 2 shows a preferred embodiment of the invention.

Although the invention is described with reference to shims used during the assembly of superconducting magnets, it has applicability in the field of packaging generally.

Referring to FIG. 1, a shim tray 1 of the prior art includes a container body 2, a lid 3 and a suitably dimensioned packer 4. In use, one or more shims 5 are placed in the body 2 before the lid 3 is replaced with the packer 4 located between the lid 3 and the shims 5 thus serving to retain the latter without allowing movement within the container 1.

Referring to FIG. 2 a resilient member 7 is included which could be located at a number of points in the container including, for example, on the base of the body. In the present embodiment the member 7 is conveniently located on the lid 3 and engages the contents of the container (in this example shims 5) to prevent movement thereof when the lid is closed. Since member 7 is resilient, it can deform to suit various dimensions of contents (i.e. various numbers of shims) while providing the force necessary to prevent movement.

The lid could attach to the body by a number of means including, for example, a screw fit but in this preferred embodiment, the lid is attached to the body by a hinge 8 and is held in the closed position by a snap fit catch 9. This arrangement readily lends itself to manufacture of the lid and body as a single integrated unit by techniques such as injection moulding.

A number of types of resilient member 7 is possible including a coil spring or an elastomeric block fastened to the lid (or body) by suitable means. In this preferred embodiment, a spring tongue serves as the resilient member 7. The spring tongue has the advantage that it readily lends itself to manufacture with the lid 3 (or the body) as a single integrated unit by, for example, injection moulding technology. Morever, inclusion of an opening (slot 10) in the wall of the container means that a shim can be inserted through the slot 10 to be engaged by the tongue and retained, without removing the lid.

1. A container comprising a body, a lid and a resilient member arranged so that, on closing the lid on the body, the resilient member engages any contents of the container to prevent movement thereof.

2. The container of claim 1, where the resilient member is located on the lid.

3. The container of claim 2, where the resilient member comprises a spring tongue.

4. The container of claim 3, where the spring tongue and the lid form a single integrated unit.

5. The container of claim 4, where the lid is attached to the body by a hinge.

6. The container of claim 5, where the lid is retained in the closed position by means of a snap-fit catch.

7. The container of claim 6, and further including an opening, arranged to facilitate the passing or articles therethrough to engage with the spring tongue and by retained thereby.

8. The container of claim 7, where the body, lid and spring tongue are formed as a single integrated unit.

9. The container of claim 8, formed by injection moulding.

10. A container as described in the accompanying text with reference to FIG. 2.
